(19) United States
(12) Patent Application Publication
(10) Pub. No.: US 2019/0186009 A1
(43) Pub. Date: Jun. 20, 2019

(54) SYSTEM FOR FORMING COMPOSITIONALLY-GRADED THIN FILMS

(71) Applicant: Eastman Kodak Company, Rochester, NY (US)

(72) Inventors: Lee William Tutt, Webster, NY (US); Carolyn Rae Ellinqer, Rochester, NY (US)

(21) Appl. No.: 16/150,325

(22) Filed: Oct. 3, 2018

Related U.S. Application Data
(63) Continuation-in-part of application No. 15/846,561, filed on Dec. 19, 2017.

(51) Int. Cl. C23C 16/455; C23C 16/52; C23C 16/458; C23C 16/40

(52) U.S. Cl. CPC C23C 16/45529; C23C 16/45544; C23C 16/40; C23C 16/52; C23C 16/4584; C23C 16/45553

(57) ABSTRACT

A spatial atomic layer deposition system is provided to fabricate a compositionally-graded thin film. A mixing system provides a homogeneous gaseous mixture having a controllable ratio of first and second reactive gaseous species. The first and second reactive gaseous species each react with a third reactive gaseous species but do not react with each other. A deposition unit includes first and second reactive gas zones. The homogeneous gaseous mixture is provided to the first reactive gas zone, and the third reactive gaseous species is provided to the second reactive gas zone. The mixing system is controlled to change the ratio of the first and second reactive gaseous species as a function of time as the substrate is moved relative to the deposition unit such that the deposited material has a variable composition as a function of height above the substrate.

### CROSS-REFERENCE TO RELATED APPLICATIONS

This application is a continuation-in-part of prior U.S. patent application Ser. No. 15/846,56, filed Dec. 19, 2017, entitled “Thin-film optical device with varying layer composition”, by L. Tutt, which is incorporated herein by reference in its entirety. Reference is made to commonly assigned, co-pending U.S. patent application Ser. No. ______ (Docket K002221US02), entitled “Process for forming compositionally-graded thin films”, by L. Tutt et al., which is incorporated herein by reference.

### FIELD OF THE INVENTION

This invention pertains to the field of thin films with a composition gradient and more particularly to compositionally-graded thin films fabricated using a spatial atomic layer deposition process.

### BACKGROUND OF THE INVENTION

Thin films having composition gradients are useful for their mechanical, physical, electrical and optical properties. Functionally graded materials have a continuous distribution of materials, and have been used in designing electronic, biological and optical materials. Compositionally-graded inorganic thin films are useful as encapsulants, providing improved mechanical properties over inorganic thin films of a uniform composition.

Rugate filters, also known as gradient index reflection filters, are an example of an optical application of compositionally-graded thin films. Rugate filters differ from discrete stacked filters in that the index of refraction varies as a function of the height (i.e., the z-location) within the deposited film. Typically, the optical thickness of the refractive index period determines the reflection band position, and the amplitude of the variation of the index of refraction determines the reflection bandwidth. As generally known, multiple reflection bands can be generated by serially depositing individual index of refraction profiles for each reflection band or, alternatively, by superimposing multiple index of refraction profiles and depositing the bands in parallel. The use of superposition allows for increased film complexity without adding to the mechanical thickness of the deposited film. In instances where superimposed indices exceed the material indices or result in excessively high slew rates of the material sources, both serial and parallel techniques can be used.

The typical technique for forming compositionally-graded films is the co-sputtering of multiple materials and changing the ratio of the deposited materials. This technique is relatively fast but involves the use of a vacuum chamber and produces a large amount of waste due to the need to position the sample at a sufficient distance to achieve relatively good uniformity. Rotation of the sample to achieve uniformity, which is effective, means that the deposition must be slow enough that the changes in the ratio of deposited material are still applied uniformly during the rotations. Other vacuum processes have been used for fabricating compositionally-graded thin films including pulsed laser deposition (PLD), sputtering, chemical vapor deposition (CVD), and atomic layer deposition (ALD), which all suffer from similar issues to co-sputtering. Recently, sol-gel processes have been used, and while an atmospheric process precise control of the gradient within the thin film is difficult to achieve.

Atomic layer deposition (ALD) is known to yield extremely precise layer thicknesses and uniformity. ALD is a film deposition technology that can provide improved compositional control as a function of thickness (i.e., compositional resolution) and conformal capabilities, compared to other deposition techniques. The ALD process segments the conventional thin-film deposition process into single atomic-layer deposition steps. Advantageously, ALD steps are self-terminating and can deposit one atomic layer when conducted up to or beyond self-termination exposure times. An atomic layer typically ranges from about 0.1 to about 0.5 molecular monolayers, with typical dimensions on the order of no more than a few Angstroms. In ALD, deposition of an atomic layer is the outcome of a physical reaction between a reactive molecular precursor and the substrate. In each separate ALD reaction-deposition step, the net reaction deposits the desired atomic layer and substantially eliminates “extra” atoms originally included in the molecular precursor. In its most pure form, ALD involves the adsorption and reaction of each of the precursors in the absence of the other precursor or precursors of the reaction. In practice, in any system it is difficult to avoid some direct reaction of the different precursors leading to a small amount of vapor phase nucleation and reaction.

The basic ALD process requires alternating, in sequence, the flux of chemicals to the substrate. The representative ALD process, as discussed above, is a cycle having four different operational stages:

1. MLₓ reaction;

2. MLₓ purge;

3. AH_{y} reaction; and

4. AH_{y} purge, and then back to stage 1.

This repeated sequence of alternating surface reactions and precursor-removal that restores the substrate surface to its initial reactive state, with intervening purge operations, is a typical ALD deposition cycle. A key feature of ALD operation is the restoration of the substrate to its initial surface chemistry condition. Using this repeated set of steps, a film can be layered onto the substrate in equal metered layers that are all alike in chemical kinetics, deposition per cycle, composition, and thickness.

As noted above, ALD has been used for making reflective interference filters having graded compositions. See for example the article “Introducing atomic layer epitaxy for the deposition of optical thin films” by D. Riihelä et al. (Thin Solid Films, Vol. 289, pp. 250-255, 1996). In this case, each layer is pure but since each layer is only about one molecular layer thick an average refractive index of a subset of layers can be made to be between two extremes by alternating high and low index layers. This approach requires a vacuum system, is relatively slow due to flushing the chamber after each pulse (each pulse depositing <1 nm), and does not yield intermediate refractive index layers, only when averaged over multiple layers. When multiple precursors are mixed and introduced there is competition for service sites and depletion of the more reactive material as the gases move farther from their introduction orifice into the chamber. The net result is a spatially varying material. If the precursors have separate orifices this only exacerbates the non-uniformity.

Spatial ALD is an embodiment of ALD where the two or more reactive precursors are separated in space and all or a portion of the sample is moved from one precursor zone to another, rather than pulsing the precursors in time as in traditional temporal ALD. In some Spatial ALD configurations, the substrate is flat and forms a wall of a micro chamber with a gas distribution head. Each reactive gas is separated from the others by an inert gas. To apply layers, the sample is moved from one reactive chamber to the next. Usually this is accomplished by moving the sample in an oscillatory or rotational fashion. In some cases, if there are enough alternating orifices of reactive and inert gases the sample can make a single pass. This would be especially beneficial to web-based deposition of very thin films.

A number of prior art references have described methods for fabricating compositionally-graded thin films for a number of different applications. U.S. Patent Application Publication 2009/0258237 to Choi et al., entitled “Graded composition encapsulation thin film comprising anchoring layer and method of fabricating the same,” discloses the use of graded composition layers for the encapsulation of organic material layers, such as those that are used in organic light emitting devices (OLEDs). Choi et al. employ physical vapor deposition (PVD) processes for the formation of the thin-film layer. Broadly, PVD process are those that transfer a material from a source to a substrate by vaporizing the source material. These are typically vacuum processes and include sputtering, pulsed laser deposition (PLD), ion beam deposition (IBD), and ion beam assisted deposition (IBAD). These processes suffer from the short comings noted above—namely high materials waste, difficulty in precise gradient control, and vacuum processing. As such, it is desired to have a process to form compositionally-graded thin-film layers for encapsulation, that can deliver precise control of the composition but avoids vacuum processing and has low material waste.

An article by Y.-H. Choi et al., entitled “Design and fabrication of compositionally graded inorganic oxide thin films: Mechanical, optical and permeation characteristics” (Acta Materialia, Vol. 50, pp. 6595-6503, 2010) similarly discloses co-sputtering as a method to form compositionally-graded films for encapsulation. Similarly, an article by Y. Wang et al., entitled “On the novel biaxial strain relaxation mechanism in epitaxial composition graded La₁₋ₓSrₓMnO₃ thin film synthesized by RF magnetron sputtering” (Coatings, Vol. 5, pp. 802-815, 2015) also discloses the use of co-sputtering to form compositionally-graded films.

U.S. Pat. No. 9,056,331 to Bulliard et al., entitled “Thin layer having composition gradient and production method thereof,” also discloses the use of graded composition layers for the encapsulation of organic material layers. Lee et al. use a sol-gel process to form the compositionally-graded thin film encapsulation layer, alone or in combination with PVD. The sol-gel process is limited in ability to precisely control the composition of the graded film, while changes in the composition-gradient are possible with different sol-gel conditions, there is no ability to design an exact profile or to create complex gradients in a single process. As such, there remains a need for a high-precision process that can form complex compositional profiles.

An article by G. Riveros et al., entitled “Electrodeposition and characterization of composition-graded CdSₓSe₍₁₋ₓ₎ multilayer thin film structures” (Journal of Alloys and Compounds, Vol. 686, pp. 235-244, 2016) discloses the formation of composition-graded stacked layer samples by electrodeposition. As disclosed, the graded thin films are deposited using a time consuming wet chemistry technique which requires that the thin film be at least semi-conducting. This approach does not address the need for a fast, easy process to deposit compositionally-graded thin films. Additionally, there are applications in electronics for using compositionally-graded thin films to control the bandgap of semiconductor materials layers.

There remains a need for a process which enables control of the composition gradient, without requiring the flushing of gases or the concomitant waste of materials. Furthermore, there is a need for a technique capable of rapid deposition of compositionally-graded thin films on a wide range of substrates without the use of a vacuum.

### SUMMARY OF THE INVENTION

The present invention represents a spatial atomic layer deposition system for fabrication of a compositionally-graded thin film, including: a substrate support mechanism for supporting a substrate, the substrate having a substrate surface;

a deposition unit having a first reactive gas zone and a second reactive gas zone;

a mixing system that provides a first reactive gaseous material including a controllable ratio of a first reactive gaseous species and a second reactive gaseous species;

a gas delivery system for supplying the first reactive gaseous material to the first reactive gas zone and a second reactive gaseous material including a third reactive gaseous species to the second reactive gas zone;

a relative motion system for causing relative motion between the deposition unit and the substrate according to a specified motion profile such that the substrate is sequentially exposed to the first and second reactive gaseous materials in the first and second reactive gas zones, respectively, thereby depositing material on the substrate; and

a controller for controlling the mixing system to vary the ratio of the first and second reactive gaseous materials during the relative motion such that the combination of the controlling the mixing system and the motion profile causes the deposition of a thin film having a variable composition as a function of height above the substrate surface.

This invention has the advantage that it enables the formation of a thin film having a variable composition as a function of height above the substrate without the use a vacuum chamber.

It has the additional advantage that the variable composition thin film is rapidly generated with molecular layer precision.

### BRIEF DESCRIPTION OF THE DRAWINGS

FIG. 1 is schematic block diagram showing the functional elements of an SALD deposition system;

FIGS. 2A-2C are cross-sectional side views of SALD deposition heads useful in the present invention having a single ALD cycle;

FIG. 3A is a cross-sectional side view of an alternative embodiment of an SALD deposition head having 1.5 ALD cycles;

FIG. 3B is a plan view of the SALD head of FIG. 3A;

FIG. 4 is a high-level diagram showing the components of a system for deposition of a gradient index optical filter according to an embodiment of the present invention;

FIG. 5 is a graph showing a refractive index profile specifying the refractive index versus height above the substrate for a two-band reflector;

FIG. 6 is a graph showing the calculated reflection spectrum of a thin-film interference filter generated from the refractive index profile of FIG. 5;

FIG. 7 is a graph showing measured refractive index as a function of the percentage of the first reactive precursor in the homogeneous gaseous mixture;

FIG. 8 is a graph showing measured growth per oscillation as a function of the percentage of the first reactive precursor in the homogeneous gaseous mixture;

FIG. 9 is a graph showing the experimental reflection spectrum of a thin-film interference filter generated according to the refractive index profile of FIG. 5; and

FIG. 10 is a graph showing the experimental reflection spectrum of a thin-film interference filter generated based on the refractive index profile of FIG. 5 where the heights above the substrate are stretched by 15%;

It is to be understood that the attached drawings are for purposes of illustrating the concepts of the invention and may not be to scale. Identical reference numerals have been used, where possible, to designate identical features that are common to the figures.

### DETAILED DESCRIPTION OF THE INVENTION

Throughout the specification and claims, the following terms take the meanings explicitly associated herein, unless the context clearly dictates otherwise. The meaning of “a,” “an,” and “the” includes plural reference, the meaning of “in” includes “in” and “on.” Additionally, directional terms such as “on,” “over,” “top,” “bottom,” “left,” and “right” are used with reference to the orientation of the figure(s) being described. Because components of embodiments of the present invention can be positioned in a number of different orientations, the directional terminology is used for purposes of illustration only and is in no way limiting. It should be noted that, unless otherwise explicitly noted or required by context, the word “or” is used in this disclosure in a non-exclusive sense.

The invention is inclusive of combinations of the embodiments described herein. References to “a particular embodiment” and the like refer to features that are present in at least one embodiment of the invention. Separate references to “an embodiment” or “particular embodiments” or the like do not necessarily refer to the same embodiment or embodiments; however, such embodiments are generally not mutually exclusive, unless so indicated or as are readily apparent to one of skill in the art. The use of singular or plural in referring to the “method” or “methods” and the like is not limiting. It should be noted that, unless otherwise explicitly noted or required by context, the word “or” is used in this disclosure in a non-exclusive sense. Even though specific embodiments of the invention have been described herein, it should be noted that the present invention is not limited to these embodiments. In particular, any features described with respect to one embodiment may also be used in other embodiments, where compatible. The features of the different embodiments can be exchanged, where compatible.

It is to be understood that elements not specifically shown, labeled, or described can take various forms well known to those skilled in the art. In the following description and drawings, identical reference numerals have been used, where possible, to designate identical elements. It is to be understood that elements and components can be referred to in singular or plural form, as appropriate, without limiting the scope of the invention.

The example embodiments of the present invention are illustrated schematically and are not to scale for the sake of clarity. One of ordinary skill in the art will be able to readily determine the specific size and interconnections of the elements of the example embodiments of the present invention. Therefore, the provided figures are not drawn to scale but are intended to show overall function and the structural arrangement of some embodiments of the present invention.

The embodiments of the present invention relate components for systems useful for thin-film deposition. In preferred embodiments, the thin-film deposition is done using a spatial atomic layer deposition (SALD) process. For the description that follows, the term “gas” or “gaseous material” is used in a broad sense to encompass any of a range of vaporized or gaseous elements, compounds, materials or mixtures. Other terms used herein, such as: reactant, precursor, vacuum, and inert gas, for example, all have their conventional meanings as would be well understood by those skilled in the materials deposition art. Reactant gas flows can include one or more reactive species together with an inert gas. In some embodiments, the reactive gases can include a reactive plasma, such as supplied by a remote plasma source. One type of remote plasma source that can be used includes a surface dielectric barrier discharge source. As such, plasma-enhanced spatial ALD (PE-SALD) arrangements are considered to be useful in some embodiments.

Unless otherwise explicitly noted or required by context (for example, by the specified relationship between the orientation of certain components and gravity), the term “over” generally refers to the relative position of an element to another and is insensitive to orientation, such that if one element is over another it is still functionally over if the entire stack is flipped upside down. As such, the terms “over”, “under”, and “on” are functionally equivalent and do not require the elements to be in contact, and additionally do not prohibit the existence of intervening layers within a structure. The term “adjacent” is used herein in a broad sense to mean an element next to or adjoining another element. The figures provided are not drawn to scale but are intended to show overall function and the structural arrangement of some embodiments of the present invention.

Embodiments of the present invention are illustrated and described with a particular orientation for convenience; and unless indicated specifically, such as by discussion of gravity or weight vectors, no general orientation with respect to gravity should be assumed. For convenience, the following coordinate system is used: the z-axis is perpendicular to the output face of the deposition head, the x-axis is parallel to the primary motion direction (in the plane of the output face), and the y-axis is perpendicular to the primary motion axis (in the plane of the output face).

As employed herein the term “optical coating” is intended to encompass rugate coatings that are used with radiation within the visible spectrum of wavelengths, and also coatings that are used with radiation within other wavelength bands, such as the ultraviolet (UV) and infrared (IR) spectrums.

An atomic layer deposition (ALD) process accomplishes thin-film growth on a substrate by the alternating exposure of two or more reactive materials, commonly referred to as precursors, either in time or space. A first precursor is applied to react with the substrate. The excess of the first precursor is removed and a second precursor is then applied to react with the substrate surface. The excess of the second precursor is then removed, and the process is repeated. In all ALD processes, the substrate is exposed sequentially to a series of reactants that react with the substrate. The thickness of the ALD (and SALD) deposited thin films is controlled by the number of ALD cycles to which the substrate is exposed, where a cycle is defined by the exposure to the minimum required reactant and purge gas flows to form the desired thin-film composition. For example, in a simple design, a single cycle can provide one application of a first reactant gaseous material G1 and one application of second reactant gaseous material G2. In order to effectively achieve repeated cycles, SALD requires either motion of the substrate past the deposition head or the development of complex equipment such that the delivery head with its gas connections, can be moved relative to the substrate. Thin films of appreciable thickness can be accomplished by either: 1) using a deposition head containing a sufficient number of gas distribution cycles and moving the substrate (or the deposition head) in a unidirectional motion relative to the deposition head (or substrate), or 2) using a deposition head with a limited number of cycles and using relative reciprocating motion.

In order to effectively use an SALD deposition head for thin-film deposition, it is commonly employed within a larger SALD system, or apparatus. Typically, such systems are specifically designed to deposit thin films on a particular type of substrate (for example, either rigid or flexible). Furthermore, SALD systems typically utilize a singular motion profile type that is chosen as a result of the design of the deposition head and the type of substrate being coated. In many cases, SALD systems are further designed for a specific application, and as such are configured to coat a single material at a given thickness on a substrate having a particular form factor.

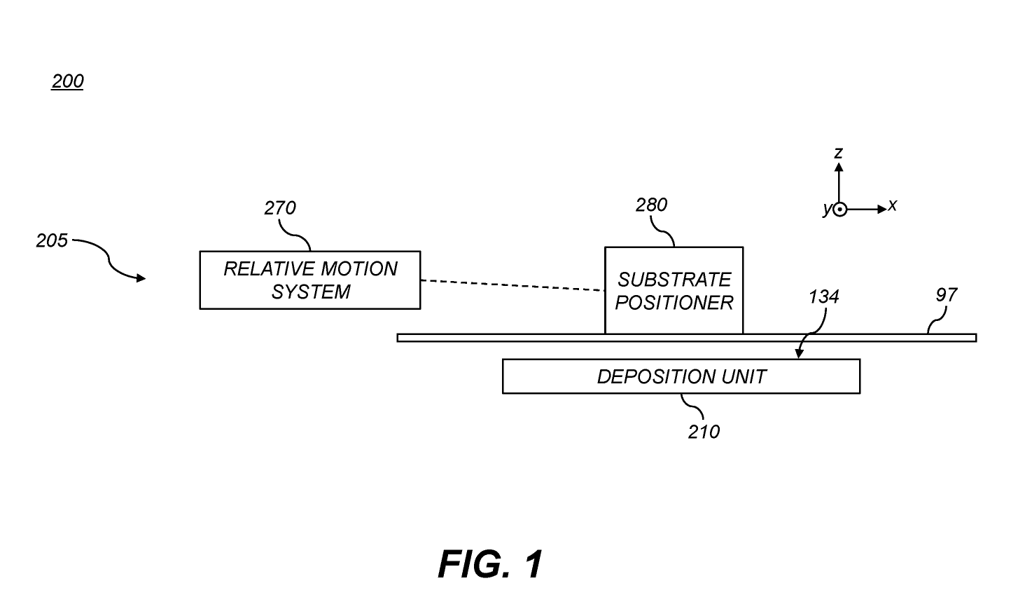

FIGS. 1, 2A-2C and 3A-3B are adapted from commonly assigned, co-pending U.S. Patent Application Publication 2018/0265978 by Spath et al., entitled “Deposition system with repeating motion profile,” which is incorporated herein by reference. Additional details regarding various SALD configurations that can be adapted for use with the present invention can be found in commonly assigned, co-pending U.S. Patent Application Publication 2018/0265976, entitled “Modular thin film deposition system,” by Spath et al.; to commonly assigned, co-pending U.S. Patent Application Publication 2018/0265977, entitled “Deposition system with vacuum pre-loaded deposition head,” by Spath et al.; to commonly assigned, co-pending U.S. Patent Application Publication 2018/0265969, entitled “Dual gas bearing substrate positioning system,” by Spath; to commonly assigned, co-pending U.S. Patent Application Publication 2018/0265982, entitled “Deposition system with moveable-position web guides,” by Spath et al.; to commonly assigned, co-pending U.S. Patent Application Publication 2018/0265979, entitled “Deposition system with modular deposition heads,” by Spath et al.; to commonly assigned, co-pending U.S. Patent Application Publication 2018/0265970, entitled “Porous gas-bearing backer,” by Spath; to commonly assigned, co-pending U.S. Patent Application Publication 2018/0265980, entitled “Deposition system with interlocking deposition heads,” by Tutt et al.; to commonly assigned, co-pending U.S. Patent Application Publication 2018/0265971, entitled “Vertical system with vacuum pre-loaded deposition head,” by Spath et al.; and to commonly assigned, co-pending U.S. Patent Application Publication 2018/0265981, entitled “Heated gas-bearing backer,” by Spath; each of which is incorporated herein by reference.

As known by one skilled in the art, each SALD system requires at least three functional elements in order to effectively deposit a thin film, namely a deposition unit, a substrate positioner and a means of relative motion. As shown in schematic block diagram of FIG. 1, SALD system 200 of the present invention is preferably one in which a substrate 97 is moved relative to a fixed deposition unit 210. As such, substrate 97 is positioned over the output face 134 of a deposition unit 210 by substrate positioner module 280, and relative motion between the substrate 97 and the deposition unit 210 is accomplished by motion of the substrate positioner module 280 using relative motion system 270, which can also be referred to as a motion controller or a motion control means. The deposition unit 210, substrate positioner module 280 and relative motion system 270 are functional elements of deposition subsystem 205 of SALD system 200. In various embodiments of the present invention, the deposition unit 210 can be a single deposition head or can be a deposition unit that include an array of deposition heads. The relative motion system 270 interacts with the substrate positioner module 280 to move the substrate 97 relative to the deposition unit 210.

Many types of substrates can be coated with the SALD system 200. The substrates 97 used in the present invention can be any material that acts as a mechanical support for the subsequently coated layers and is reactive with at least one of the reactants. The substrate 97 can include a rigid material such as glass, silicon, or metals. The substrate can also include a flexible material such as a polymer film or paper. Useful substrate materials include organic or inorganic materials. For example, the substrate can include inorganic glasses, ceramic foils, and polymeric materials. The thickness of substrate 97 can vary, typically from about 25 μm to about 1 cm. Using a flexible substrate 97 allows for roll processing, which can be continuous, providing economy of scale and economy of manufacturing relative to flat or rigid supports.

In some exemplary embodiments, the substrate 97 can include a temporary support or support material layer, for example, when additional structural support is desired for a temporary purpose, e.g., manufacturing, transport, testing, or storage. In these example embodiments, the substrate 97 can be detachably adhered or mechanically affixed to the temporary support. For example, a flexible polymeric support can be temporarily adhered to a rigid glass support to provide added structural rigidity during the deposition process. The glass support can be removed from the flexible polymeric support after completion of the manufacturing process. The substrate 97 can be bare indicating that it contains no substantial materials on its surface other the material from which it is composed. The substrate 97 can include various layers and patterned materials on the surface.

The substrate positioner module 280 is designed to position the substrate 97 in the x- and y-directions relative to the output face 134 of the deposition unit 210. The SALD system 200 may also include a secondary substrate positioner (not shown) which is designed to control the position of the substrate 97 in the z-direction.

In various configurations, the substrate 97 can be attached to a backer device during deposition, which also serves as a substrate support mechanism. The backer device can be used as heat source for the substrate, or to stiffen otherwise flexible substrates. A backer that is temporarily attached to the substrate, by vacuum for example, is intended to move with the substrate during relative motion between the substrate and a fixed deposition head. The backer attachment can provide greatly increased rigidity and flatness to flexible substrates. A substrate support mechanism useful in the present invention can be larger than the substrate, as might be used to stabilize piece-parts of flexible substrate or approximately the same size as the substrate, or significantly smaller than the substrate when the substrate is rigid and self-supporting.

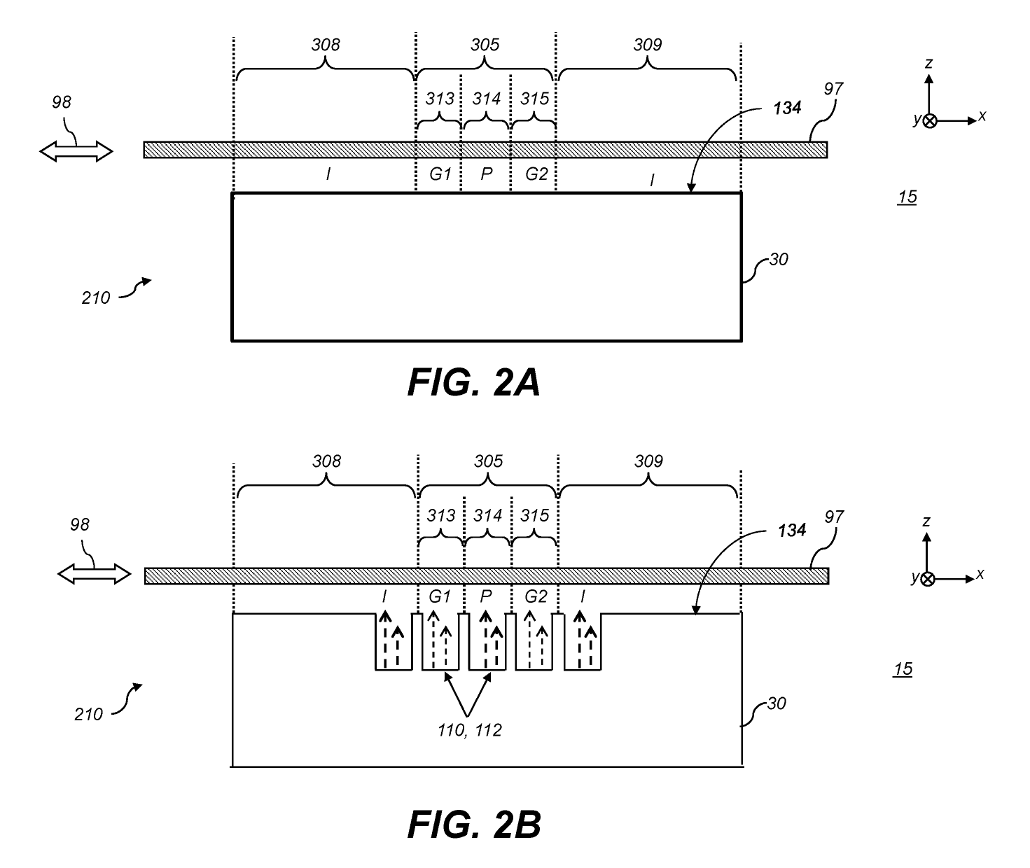

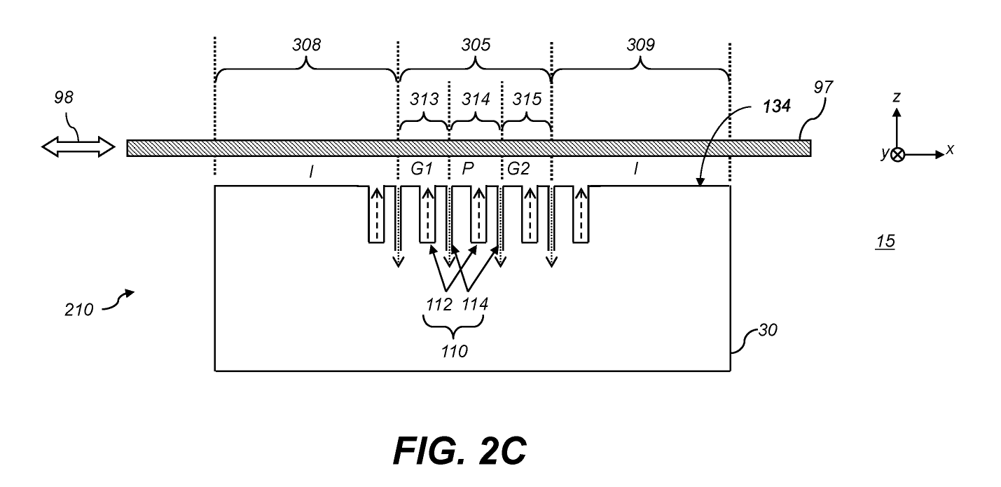

The deposition unit 210 can use any type of SALD deposition head that is known in the art. FIGS. 2A-2C illustrate deposition heads 30 that are configured to simultaneously supply a plurality of gaseous materials from the output face in different gas zones within a deposition zone 305. In all three figures, the deposition zone 305 contains the necessary gas zones for a single two-step ALD deposition cycle. Moving from left to right within the deposition zone 305, there is a first reactive gas zone 313 (G1) followed by an inert gas purge zone 314 (P), and a second reactive gas zone 315 (G2). As the relative motion system 270 (FIG. 1) moves the substrate 97 relative to the deposition head 30 (the x-direction being the primary motion direction as indicated by motion arrow 98), a particular location on the substrate 97 sees the above sequence of gases which results in ALD deposition. Deposition heads 30 of the present can include a deposition zone 305 with gas zones for any number of ALD deposition cycles, the single ALD cycle illustrated is for clarity of understanding.

The SALD systems of the present invention can use any deposition unit 210 so long it has the required gas delivery process and geometry to form first and second reactive gas zones that are separated by a purge zone. These zones may be arranged in a linear fashion as illustrated in FIGS. 1-3, or can be arranged in other geometries such as in pie-shaped sections around a central axis, or any other appropriate configuration.

In exemplary embodiments, the deposition unit has a deposition head 30 with an output face 134 for providing the gases, forming gas zones between the deposition head 30 and the substrate 97 in the required order to accomplish an ALD cycle, as illustrated by the simplified deposition head 30 of FIG. 2A. In preferred embodiments, the reactive gases (G1 and G2, for example) have little or no intermixing to avoid a vapor phase reaction component during film deposition or gas phase reactions. The purge zone 314 (P) serves to separate the reactive gases G1, G2 and allows for the removal of any reaction byproducts from the substrate surface as it moves through the purge zone 314.

A single deposition cycle (moving from left to right) is defined by an inert gas flow I, followed by a first reactive gas flow G1, followed by an inert purge gas flow P, and lastly by a second reactive gas flow G2. The deposition zone 305 has a deposition zone length that spans the distance from the start of the first reactive gas zone to the end of the last reactive gas zone (e.g., from the first reactive gas zone 313 to the second reactive gas zone 315 in FIG. 2A). The deposition heads 30 illustrated in FIGS. 2A-2C, have extended inert zones 308, 309 on either side of the deposition zone 305 where the substrate is exposed to an inert gas (I). One of the advantages of the configuration of deposition head 30 and SALD system 200 containing is that it can be used to coat on substrates 97 whose length is much larger than the length of the deposition zone 305. A further advantage of some embodiments is the ability to control the environment of the region of the substrate being actively coated during deposition. Additionally, the relatively small deposition head size allows for lower cost manufacturing of the deposition head.

The deposition head 30 of FIG. 2B illustrates an embodiment where one or more of the gas zones use a transverse arrangement, such as that disclosed in commonly-assigned U.S. Pat. No. 7,456,429 to Levy et al., entitled “Apparatus for atomic layer deposition,” which is incorporated herein by reference. In a transverse flow arrangement, the flow of gases during deposition is orthogonal, or transverse, to the direction of substrate motion and is exhausted either out the edges of the deposition head 30, or into exhaust slots along the perimeter of the deposition head 30. As illustrated, the deposition head 30 has gas slots 110 (i.e., output slots 112) that are configured to supply the gases into their corresponding gas zones. In other embodiments, the deposition head 30 provides gas to the elongated parallel gas zones through an array of orifices, rather than through the illustrated output slots 112 (elongated channels).

The deposition head 30 of FIG. 2C illustrates a preferred gas bearing deposition head 30 configuration. The principles and design of gas bearing deposition heads 30 has been described in detail in commonly-assigned U.S. Patent Application Publication 2009/0130858 to Levy, entitled “Deposition system and method using a delivery head separated from a substrate by gas pressure,” as well as in commonly-assigned U.S. Pat. No. 7,572,686 to Levy et al., entitled “System for thin film deposition utilizing compensating forces,” both of which are incorporated herein by reference. As shown in FIG. 2C, an exemplary deposition unit 210 includes a deposition head 30 that operates on a vacuum-preloaded gas bearing principle having an output face 134 (facing upward) having gas slots 110 which provide gases into the gas zones and exhaust gases from the gas zones. Gases are provided into the gas zones by spatially separated elongated output slots 112 (extending in the y-direction). Each gas zone includes a corresponding output slot 112. Adjacent exhaust slots 114 remove (or exhaust) gas from the gas zones. The exhaust slots 114 are positioned to define the boundaries of the various gas zones. As illustrated, the gas zones are equivalent to those of FIGS. 2A and 2B.

In these preferred arrangements wherein the deposition head 30 operates using a gas bearing principle the substrate 97 is positioned above the output face 134 of the deposition head 30 and is maintained in close proximity to the output face 134 by an equilibrium between the pull of gravity, the flow of the gases supplied to the output face 134 through the output slots 112, and a slight amount of vacuum at the exhaust slots 114. While the gas openings in this example are gas slots 110 (also referred to as gas channels) that extend in the y-direction, one skilled in the art will recognize that the gas openings could also have other geometries, such as a row of nozzles or circular orifices, so long as the proper gases are delivered into and exhausted from the gas zones between the deposition head and the substrate.

As shown in FIG. 2C, the gases are introduced and exhausted in alternating output slots 112 and exhaust slots 114 in the output face 134 of the deposition head 30. The flow of gases between the output slots 112 during deposition is primarily in the direction of substrate travel (forward and backward) toward the adjacent exhaust slots 114. As discussed earlier, the region that spans the reactive gas zones can be referred to as the deposition zone 305, which is preferably surrounded by two inert zones 308, 309. The individual gas zones within the deposition zone 305, where the substrate 97 is exposed to each gas, generally extend outward from the corresponding output slot 112 to the two adjacent exhaust slots 114 as illustrated for the first reactive gas zone 313, the purge zone 314, and the second reactive gas zone 315. In the illustrated configuration, the extended inert zones 308, 309 extend from the inert gas output slots 112 to the edges of the deposition head 30. In alternative embodiments, the extended inert zones 308, 309 can include additional output slots 112 or other gas supply features. Additionally, the extended inert zones 308, 309 can include exhaust slots 114, or other exhaust features, to provide additional protection/separation from the external environment 15.

Using any of the embodiments of deposition head 30 of FIGS. 2A-2C, an SALD deposition process can be accomplished by oscillating the position of the substrate 97 across the deposition head 30 (in the in-track direction indicated by the motion arrow 98) for the number of cycles necessary to obtain a uniform deposited film of the desired thickness for the given application.

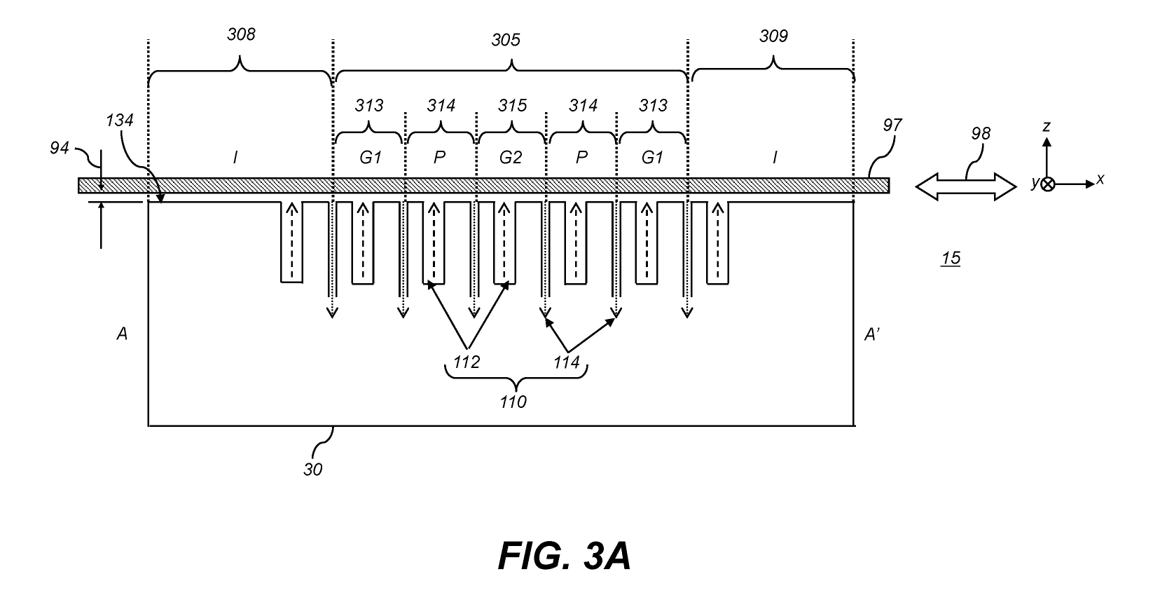

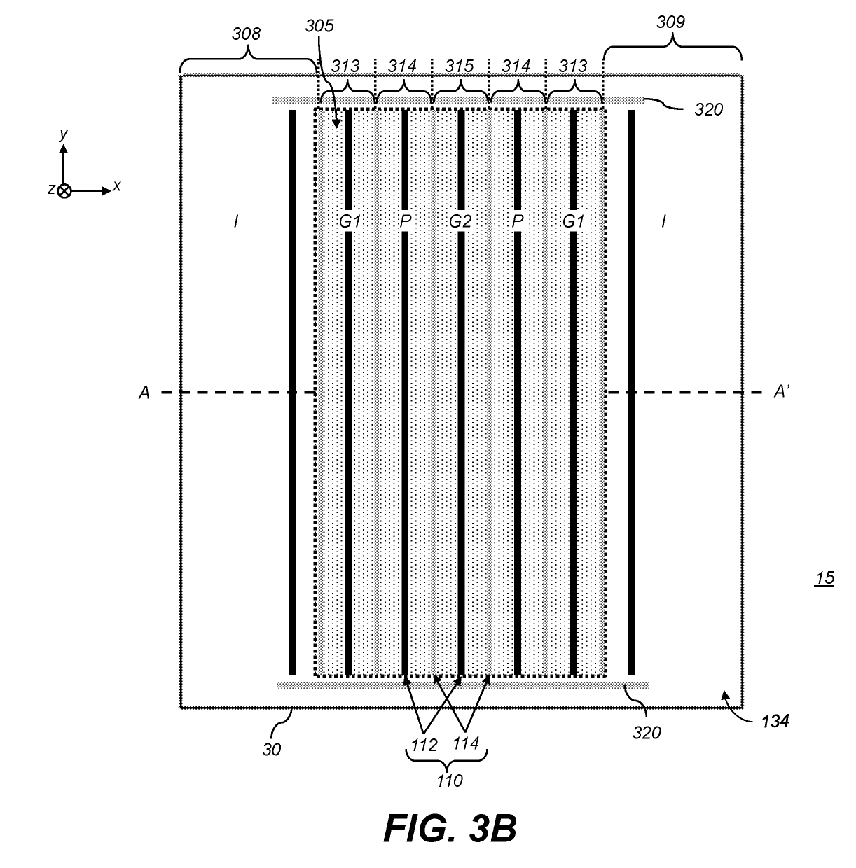

FIG. 3A is a cross-sectional view of a deposition head 30 illustrating an exemplary configuration where the deposition zone 305 is arranged to be symmetric, so that as the substrate 97 is moved relative to the deposition head 30 a position can “see” a full cycle exposure in either a forward or reverse direction. FIG. 3B illustrates a plan view corresponding to the cross-sectional view of FIG. 3A, where the cross-sectional view is taken along the line A-A′ of the plan view. In common parlance, the deposition head 30 illustrated in FIG. 3A-3B can be referred to a “one-and-a-half cycle head” or a “1.5 cycle head.” Moving from left-to-right through the deposition zone 305, the substrate 97 is exposed to (in order) a first reactive gas zone 313 where the substrate is exposed to a first reactive gas G1, an inert purge zone 314 where the substrate is exposed to an inert purge gas P, a second reactive gas zone 315 where the substrate is exposed to a second reactive G2, another inert purge zone 314 where the substrate is exposed to the purge gas P, and another first reactive gas zone 313 where the substrate is exposed to the first reactive gas G1. Moving in the reverse direction from right-to-left through the deposition zone 305, the substrate 97 is exposed to the same sequence of gases as in the forward (left-to-right) direction, namely the first reactive gas G1, the inert purge gas P, the second reactive gas G2, the inert purge gas P, and the first reactive gas G1. The advantage of this symmetry is that feeding the substrate 97 from left-to-right or right-to-left results in equivalent exposure, and entrance and exit sides of the deposition head 30 depend of the direction of relative motion of the substrate 97 not the design of the deposition head 30.

As with the previous embodiments, the gas zones (or regions) are between the substrate 97 and the deposition head 30. The labels in FIG. 3A are placed above the substrate for clarity and to further emphasize the small working distance 94 between the process-side of substrate 97 and the output face 134 of the deposition head 30 enabled by the use of a vacuum-preloaded gas bearing deposition head 30. As illustrated in the plan-view of FIG. 3B, in addition to the output slots 112 (shown as black lines) and the exhaust slots 114 (shown as gray lines) in the deposition zone 305 (shown as a shaded area), there are additional output slots 320 orthogonal to the gas slots 110 in the deposition zone 305. The additional gas output slots 320 provide inert gas to the cross-track edge region of the deposition head 30, providing further isolation of the deposition zone 305 from the external environment 15.

The exemplary gas bearing deposition head 30 of FIG. 3A has gas slots 110 corresponding to 1.5 ALD cycles to provide the proper sequence of gas exposure in the forward and reverse directions. As the substrate 97 is oscillated back and forth over the deposition head 30, it will provide only a single ALD cycle (one G1 and one G2 exposure) per single direction pass over the deposition head 30, therefore a round trip oscillation provides two ALD cycles. Furthermore, when the second precursor G2 is reactive with the external environment, while the first precursor G1 is not, this arrangement provides additional protection against unwanted reactions involving G2. An example of a precursor pair that would benefit from this arrangement is water and trimethylaluminum (TMA), where water is the non-reactive precursor G1 and TMA is the highly reactive precursor G2.

An SALD deposition head operating as a vacuum-preloaded gas bearing has been described in the aforementioned U.S. Pat. No. 7,572,686 (Levy et al.). As noted, the use of a vacuum-preloaded gas bearing can provide efficiency of materials utilization, freedom from gas intermixing, and fast reaction kinetics due to the very small gap between the substrate 97 (deposition side) and the output face 134 of the deposition head 30.

Inlet ports (not shown in FIGS. 3A-3B) are used to supply the various gasses to the deposition head 30. When there are multiple gas slots 110 that supply the same gas, a single inlet port is typically used to supply the gas, and a manifold is used to distribute the gas to the appropriate gas slots 110. For example, a first inlet port can provide a supply of the first reactive gas G1 to the deposition head 30, and a first manifold can direct the gas to the output slots 112 in the first reactive gas zones 313. A second inlet port can provide a supply of the second reactive gas G2 to the deposition head 30, and a second manifold can direct the gas to the output slot 112 in the second reactive gas zones 315. A third inlet port can provide a supply of the purge gas P to the deposition head 30, and a third manifold can direct the gas two the output slots 112 in the purge zones 314. Typically, the purge gas G and the inert gas I are the same gas. In this case, the third manifold can also direct the purge gas to the output slots 112 in the inert zones 308, 309. Otherwise, a separate inlet port can be provided for the inert gas. Likewise, the exhaust slots 114 are connected to one or more exhaust ports using corresponding gas manifolds. Because the exhaust gases may still contain quantities of unreacted precursors, it may be undesirable to allow an exhaust flow predominantly containing one reactive species to mix with one predominantly containing another species. As such, the deposition head 30 may contain several independent exhaust conduits.

Depending on the relative sizes of the deposition head 30, the first and second reactive gas zones 313, 315, the purge zones 314 and the substrate 97, some parts of the surface of the substrate 97 can be simultaneously exposed to the first and second reactive gases G1, G2. For example, if the substrate 97 is larger than the deposition head 30, or if the purge zone 314 is smaller than the substrate 97 a first portion of the substrate 97 will be exposed to the first reactive gas G1 in the first reactive gas zone 313 at the same time a second portion of the substrate 97 is being exposed to the second reactive gas G2 in the second reactive gas zone 315. On the other hand, if the purge zone 314 is larger than the substrate 97, then the entire substrate will be exposed to the first reactive gas G1 prior to being exposed to the second reactive gas G2.

As mentioned earlier, the gas zones in the SALD deposition can have any geometry. In addition to the linear gas zone arrangement that has been described, another class of SALD deposition geometries includes gas zones arranged circularly around a central axis. An example of such an SALD system useful for wafer processing is illustrated U.S. Pat. No. 9,514,933 to Lei et al., entitled “Film deposition using spatial atomic layer deposition or pulsed chemical vapor deposition.” In this case, the deposition unit provides a series of gas zones in a radial configuration, and the substrate is transported through the gas zones on a rotating platen in a circular motion profile. Other useful SALD configurations are discussed in the article “Spatial atomic layer deposition: A route towards further industrialization of atomic layer deposition” by P. Poodt et al. (Journal of Vacuum Science Technology A, Vol. 30, 010802, January/February 2012). It should be understood to one skilled in the art that any of these SALD configurations have deposition units with the necessary first and second reactive gas zones, and can be used in accordance with the present invention by providing time-varying gas mixtures to one or both of the reactive gas zones by using a controller 600 to control appropriate mixing systems 640, 645.

In some SALD configurations, a portion of the substrate may be exposed with each gas zone (as illustrated in FIGS. 1-3) or alternatively, the entire substrate can be exposed within each reactive gas zone. In embodiments where the entire substrate is exposed to the first reactive gaseous material prior to being exposed to the second reactive gaseous material, the substrate is moved from zone to zone similarly to the illustrated SALD system however the gas zones are large enough to accommodate an entire substrate. When depositing layers on substrates of finite size, such as wafers or glass parts, this can be advantageous.

In typical SALD configuration, the first reactive gaseous material G1 can be an oxygen or chalcogenide containing gaseous material (0); and the second reactive gaseous material G2 can be a metal-containing compound (M), such as a material containing zinc. The inert gaseous material I (which in an exemplary embodiment will be assumed to be the same as the purge gas P) can be gases such as nitrogen, argon or helium. The inert gaseous material I is inert with respect to first and second reactive gaseous materials M and O.

While the operation of the SALD configurations has been described with respect to a first reactive gaseous material G1 and a second reactive gaseous material G2, it should be understood that the first and second reactive gas zones 313 and 315 can contain additional gases. For example, in some configurations the first reactive gas zone 313 can contain a mixture of first reactive gaseous material G1 and an inert gas, and similarly the second reactive gas zone 315 can contain a mixture of the second reactive gaseous material G2 and an inert gas. In the present invention, both the first reactive gas zone 313 and the second reactive gas zone 315 can contain a mixture of multiple reactive species, so long as they meet the requirements necessary to accomplish ALD film growth. Commonly-assigned U.S. Pat. No. 8,361,544 to Fedorovskaya et al., entitled “Thin film electronic device fabrication process,” which is incorporated herein by reference, discloses the use a mixture of reactant gases, for example, a mixture of metal precursor materials or a mixture of metal and non-metal precursors which may be applied at a single output channel.

In accordance with the present invention, two or more reactive precursor gases are present in first reactive gas zone 313. In an exemplary embodiment using delivery head 30, gas streams from gas sources for the two or more reactive precursor gases are combined before exhausting from an output slot 112 in the delivery head 30. This is preferably obtained by joining the gas flows external to the delivery head 30 but may occur in the delivery head 30 if the gases are sufficiently mixed before impingement on the surface of the substrate 97. Two precursors are required (e.g., reactants M₁ and M₂) that do not chemically interact with each other, at least at the temperature of the deposition head 30. Both precursors will react with a third precursor (e.g., reactant O). The reactions yield M₁O and M₂O respectively. When the M₁ and M₂ precursors are mixed and react with the substrate surface which is terminated with O, a mix of M₁O and M₂O results. In a preferred configuration, the M₁O and M₂O precursors are chosen such that the respective refractive indexes (or other material properties) of the films are substantially different. It should be understood that M₁O and M₂O are abbreviations for the compounds formed and should not limit the present invention to metal-oxide. Furthermore, it should be understood that the exact stoichiometry of the thin-film materials will depend on the precursors used in the process.

For fabricating compositionally-graded thin films, examples of useful M₁O and M₂O compounds are TiO₂ and Al₂O₃, which can be deposited by spatial ALD, and have refractive indexes of 2.4 and 1.6, respectively. Generally, M₁O and M₂O can be chosen to be any materials whose properties are complementary, whose precursors have the attributes mentioned, and that can provide the desired properties in the compositionally-graded thin films. In the fabrication of Rugate filters, for example, any high refractive index materials may be used when coupled with a low refractive material as long as the precursors have the attributes mentioned and are not significantly absorbing at the desired wavelengths. Example high refractive index materials include ZnO, ZrO₂, HfO₂. An example low refractive index material is SiO₂.

Two metal precursors which do not react until higher than 200° C. are trimethyl aluminum and titanium tetrachloride. When used with water as the co-reactant, it is possible to deposit a film of any refractive index between 1.6 and 2.4. The ability to obtain a specific refractive index is directly attributable to the thin-film composition. In fact, refractive index is a useful measurable property to determine the composition of functionally-graded thin films for use in applications other than optics.

For visible wavelength filters, exemplary materials for substrate 97 are BK-7, fused silica, and sapphire. For IR wavelength filters, exemplary materials for substrate 97 are sapphire, zinc selenide, and germanium.

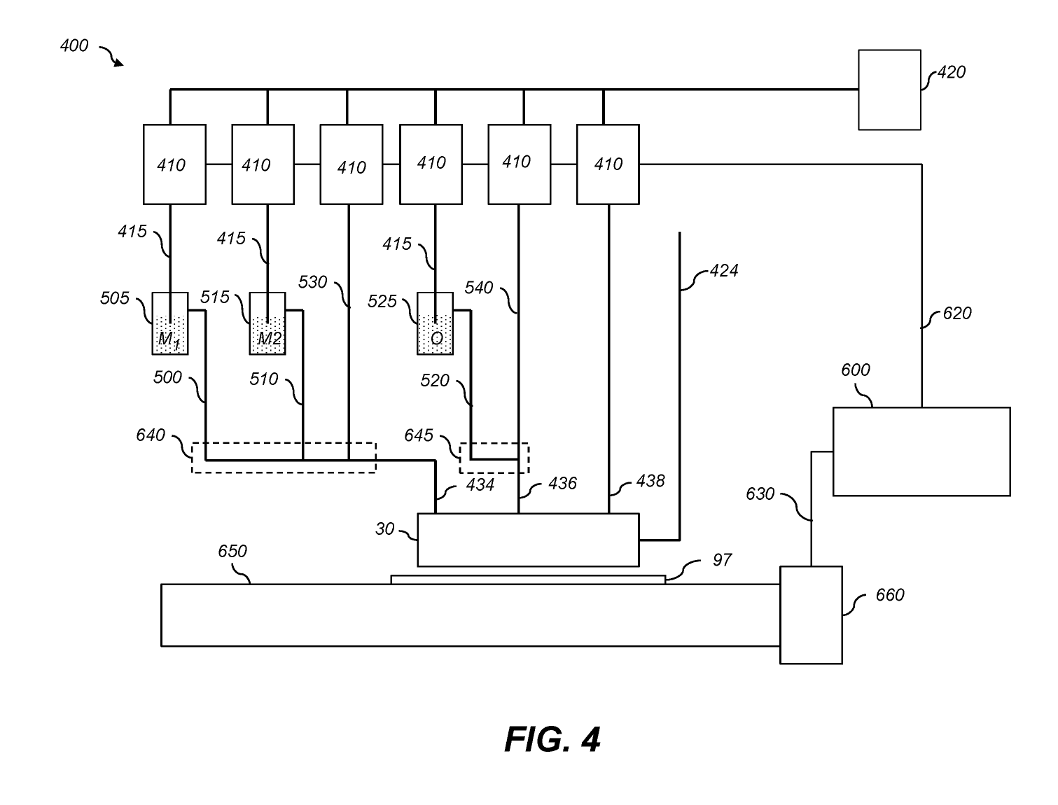

A diagram illustrating a deposition system 400 is shown in FIG. 4. In an exemplary embodiment, controller 600 (which can also be referred to as a computer) controls the gas flows through deposition head 30 to form a compositionally-graded thin film on substrate 97, such that the layers of deposited material have a uniform composition in the plane of the substrate, and vary as a function of thickness in the z-direction (i.e., height above the substrate). The controller 600 has access to information necessary to control the gas flows in order to achieve a layer of deposited material having a specified refractive index for each oscillation of the substrate 97 over the deposition head 30 in order to form a thin-film coating having a specified refractive index, or other material property, as a function of height. This information is generated from data characterizing the refractive index and the growth rate of the deposited thin film as a function of the ratio of the M₁ and M₂ precursors. The information for the gas flows is transmitted along wiring 620 to control mass flow controllers 410 in sync with the motion of the substrate 97.

The controller 600 also controls the motion of the substrate 97 by communicating signals to a motor 660 (or to a motor controller) through wiring 630. Typically, the substrate 97 is oscillated back and forth on a stage 650 with an acceleration at each reversal of direction and an intervening interval of constant velocity. Movement of the substrate 97 in a forward direction and then back in a reverse direction is considered to be an “oscillation.” The oscillation of the substrate is one method of achieving relative motion between the deposition unit and the substrate surface, alternatively other types of motion profiles are possible, including moving the deposition head 30 over a stationary substrate 97, or moving both the deposition head 30 and the substrate 97. In alternative system designs, the substrate 97 rotates at a continuous velocity through gas zones positioned around a central axis. Alternate motion profiles are also within the scope of the present invention, including variations in velocity as a function of film height or other such variations.

The deposition head 30 and the stage 650 (i.e., the substrate support mechanism) are preferably heated by a thermal heater, radiant heater, or any other method known to those skilled in the art. The stage 650 in FIG. 4 is shown moving the substrate 97 below the deposition head but it could be in any orientation (e.g., in an inverted orientation or a vertical orientation).

Bubblers 505 and 515 are fed by separate inert gas conduits 415 controlled by corresponding mass flow controllers 410 which receive an inert gas flow from an inert gas source 420. The bubblers 505 and 515 contain first and second reactive precursors (e.g., metal precursors M₁ and M₂), respectively. The output of the bubbler 505 is a gas flow including a first reactive gaseous species (e.g., the metal precursor M₁) flowing through a first reactive gas species conduit 500. Likewise, the output of the bubbler 515 is a gas flow including a second reactive gaseous species (e.g., the metal precursor M₂) flowing through a second reactive gas species conduit 510. The bubbler 505, together with the first reactive gas species conduit 500, the inert gas source 420, and the corresponding mass flow controller 410 and inert gas conduit 415 can be considered to be a first gaseous source which provides a gas flow of the first reactive gaseous species M₁. Likewise, the bubbler 515, together with the first reactive gas conduit 510, the inert gas source 420, and the corresponding mass flow controller 410 and inert gas conduit 415 can be considered to be a second gaseous source which provides a gas flow of the second reactive gaseous species M₂.

The gas flows of the first and second reactive gaseous species are combined in a mixing system 640, together with an inert gas flow in an inert gas conduit 530, to provide a first reactive gaseous material having a homogeneous gaseous mixture of the first and second reactive gaseous species and the inert gas to gas inlet conduit 434. In an exemplary embodiment, the mixing system 640 is simply a series of conduit joints where the gas flows through the individual conduits are merged into a combined gas flow. With this arrangement, the gaseous elements in the individual gas flows will mix together to provide the homogeneous gaseous mixture. Other types of mixing systems 640 can also be used including those which include active or passive mixing devices which can be used to speed the formation of the homogeneous mixture. An example of an active mixing device would be a stirring device which stirs the gas flow as it passes through the mixing system 640. An example of a passive mixing device would be a series of baffles which the gas flow passes through to redirect the gas flow. The controller 600 controls the concentrations and the ratio of the first and second reactive gaseous species in the first reactive gaseous material, together with the total gas flow through the gas inlet conduit 434, by controlling the corresponding mass flow controllers 410.

Similarly, bubbler 525 is fed by inert gas conduit 415 and controlled by a corresponding mass flow controller 410 which receives an inert gas flow from the inert gas source 420. The bubbler 525 contains a third reactive precursor (e.g., reactant O). The output of the bubbler 525 is a gas flow including the third reactive gaseous species (e.g., the reactant O) flowing through a third reactive gas species conduit 520. The bubbler 525, together with the third reactive gas species conduit 520, the inert gas source 420, and the corresponding mass flow controller 410 and inert gas conduit 415 can be considered to be a third gaseous source which provides a gas flow of the third reactive gaseous species. This gas flow is combined with an inert gas flow in an inert gas conduit 540 using a mixing system 645 to provide a gas flow of a second reactive gaseous material including the third reactive gaseous species through gas inlet conduit 436. The controller 600 controls the concentration of the third reactive gaseous species, together with the total gas flow provided through the gas inlet conduit 436, by controlling the corresponding mass flow controllers 410.

The first reactive gaseous material including the homogeneous gaseous mixture of the first and second reactive gaseous species (e.g., reactants M₁ and M₂) flowing through the gas inlet conduit 434, and the second reactive gaseous material including the third reactive gaseous species (e.g., reactant O) flowing through the gas inlet conduit 436 enter the deposition head 30, together with an inert purge gas flowing through gas inlet conduit 438. Gas manifolds in the deposition head 30 are used to direct the gas flows to the appropriate reactive gas zones (e.g., through the output slots 112 in the geometry illustrated in FIG. 3A) in order to provide the desired ALD process onto the substrate 97 as it is moved relative to the gas zones 313, 314, 315. Gases are continuously exhausted from the deposition head 30 illustrated in FIG. 3A through exhaust slots 114 and then through one or more exhaust conduits 424, which are generally connected to corresponding vacuum systems. The components used to supply the gaseous materials to the gas zones of the deposition head 30 can collectively be referred to as a gas delivery system.

It may be appreciated that the bubblers 505, 515, 525 are only used for cases where the reactive precursors are liquids. In other embodiments, one or more of the reactive precursors can be gaseous materials. In this case, the reactive gaseous materials can be supplied by a corresponding gas source and controlled directly with an associated mass flow controller.

To generate a compositionally-graded thin-film, it is necessary to know both the refractive index (or other material property) and the growth rate for different ratios of the first and second reactive gaseous species in the homogeneous gaseous mixture of the first reactive gaseous material. Usually this can be obtained by direct measurements of uniform thick films. With that information, the appropriate gas flows needed to provide the appropriate ratios for each oscillation of the substrate 97 can be calculated. A table of the required gas flows can be predetermined, or the information can be generated by the system using the calibration information and desired film properties. This information can then be used to control the mass flow controllers 410 in sync with the motion of the substrate 97 relative to the deposition head 30. For use in the exemplary oscillating system, the syncing can be closed loop where after each oscillation a signal is sent to the controller 600 to transmit the information to the mass flow controllers 410. The syncing can also be open loop where the length of time for each ALD cycles within the motion profile is known and the information is transmitted to the mass flow controllers 410 at the appropriate time.

### Example #1

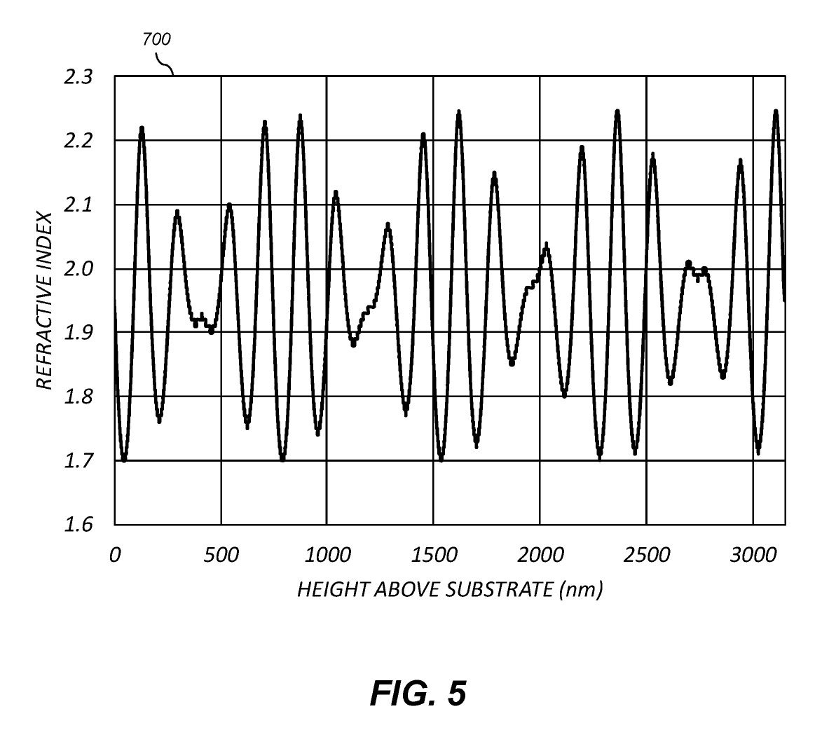

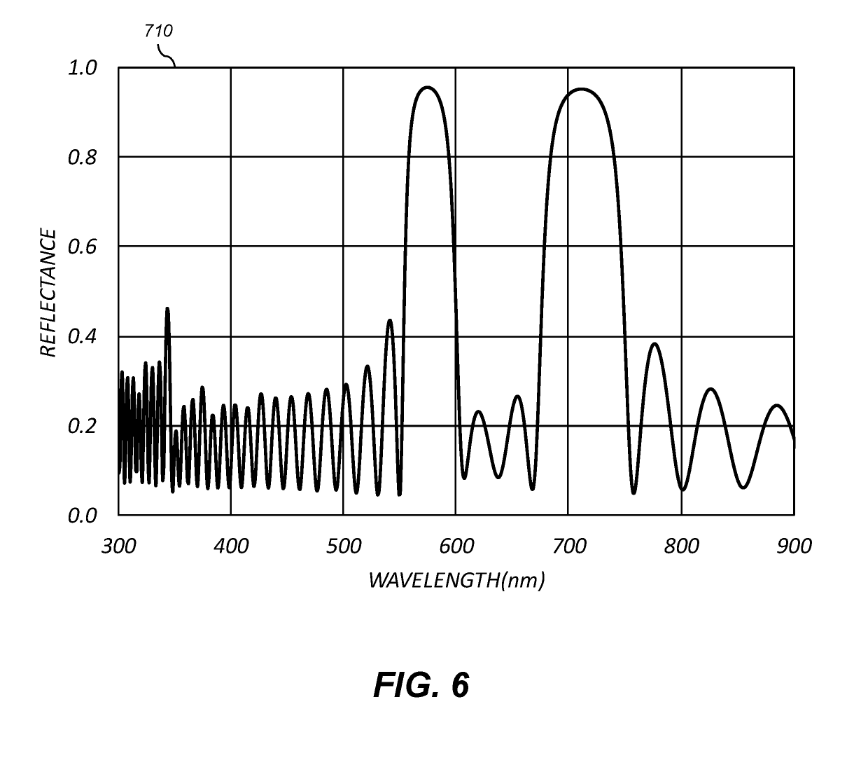

The open source program Openfilters was used to generate a target refractive index versus height above substrate profile for a two-band reflection filter having bands centered on 580 nm and 710 nm. FIG. 5 is a graph 700 showing the resulting target refractive index versus height from substrate, and FIG. 6 is a graph 710 showing the corresponding calculated reflection spectrum. This reflection filter is an example of an optical interference filter or rugate filter composed of a compositionally-graded thin film.

A filter design was determined where the first reactive precursor M₁ was titanium tetrachloride (TiCl₄) and the second reactive precursor M₂ was trimethyl aluminum (TMA). The flow rates of the first and second reactive gaseous species were controlled by mass flow controllers 410 passing dry nitrogen through bubblers 505, 515 containing the reactive precursors. The total gas flow of nitrogen passing through the bubblers 505, 515 always totaled 25 sccm. They were mixed with a 1500 sccm dilution of dry nitrogen through inert gas conduit 530 and provided to the metal output slots 112 (FIG. 1) on the deposition head 30. Water was used as the oxygen source using 40 sccm through bubbler 225 and was mixed with a 2250 sccm dilution of dry nitrogen through inert gas conduit 540 and provided to the oxygen output slots 112. The metal and oxygen output slots 112 were separated by purge gas output slots 112 supplied by dry nitrogen at 3000 sccm.

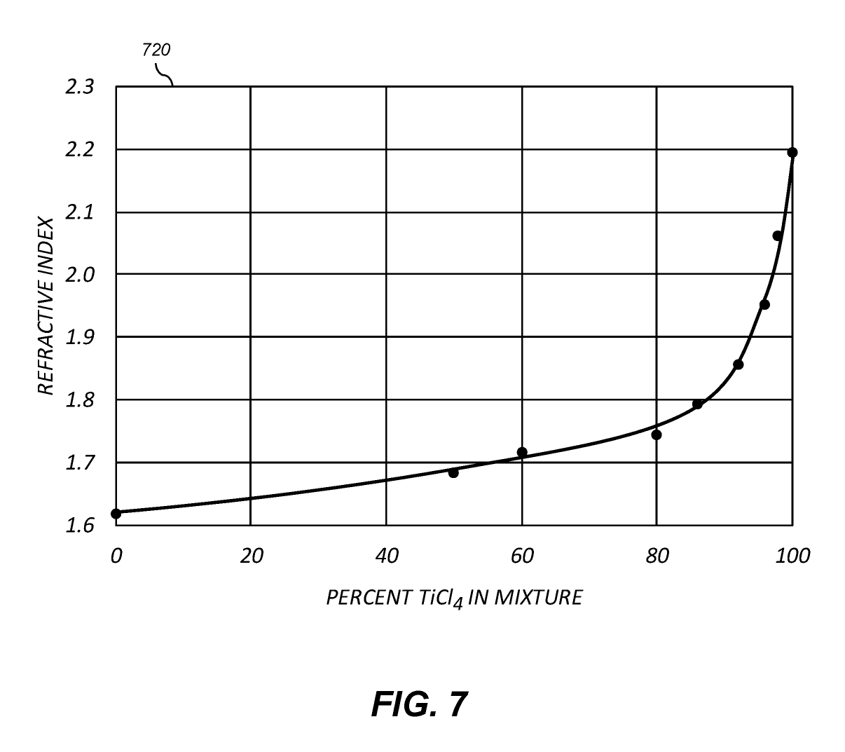

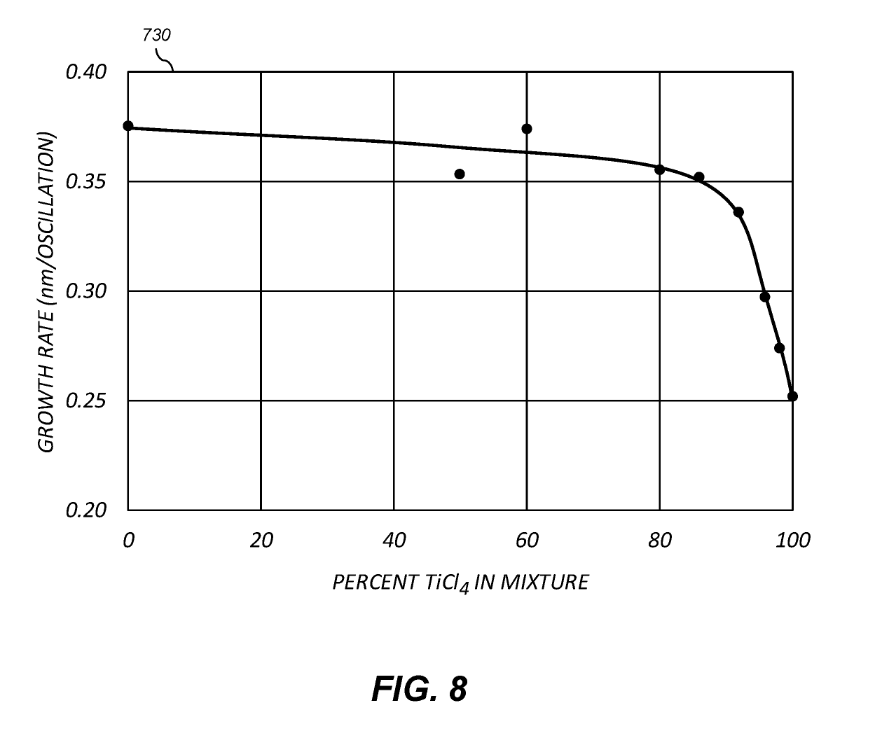

The refractive index as a function of the percentage of TiCL₄ in the homogeneous gaseous mixture was determined experimentally using the deposition system 100 (FIG. 3) to deposit thin films on a BK-7 glass substrate 97. The resulting first calibration function is shown in graph 720 of FIG. 7. The growth per oscillation as a function of the percentage of TiCL₄ in the homogeneous gaseous mixture was also determined and the resulting second calibration function is shown in graph 730 of FIG. 8. The deposition head 30 included 2.5 cycles, arranged similarly to the 1.5 cycle configuration of FIG. 3B, providing four ALD cycles per oscillation. The refractive index profile of FIG. 5 was used in conjunction with the calibration functions of FIGS. 7-8 to determine a table of gas flows versus oscillation number required to form an interference filter having the reflection spectrum shown in FIG. 5.

A BK-7 glass substrate 97 was placed over the deposition head 30. The controller 300 was loaded with the data for the flow rates versus oscillation number. A total of 10,436 oscillations were used where four ALD cycles were deposited per oscillation. The acceleration/deceleration was set to 1920 mm/sec² and the substrate velocity was 101.6 mm/sec. The total distance traveled by the substrate 97 was 36 mm. This gives an oscillation time of 0.74 sec. The gas flow rates were therefore adjusted every 0.74 sec.

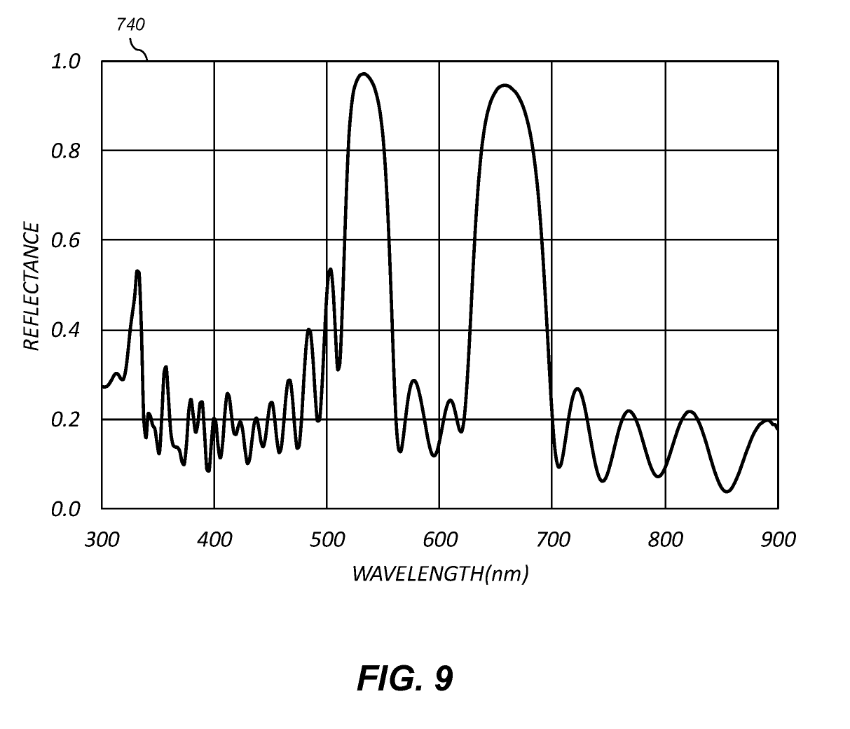

The deposition head 30 and the substrate 97 were heated to 180° C. and the program was run, finishing in 129 minutes. The resulting reflection spectrum measured at 6 degrees off axis is shown in the graph 740 of FIG. 9. Note that two reflection bands were obtained as expected. It can be seen that the peak wavelengths of the reflection bands are slightly blue shifted relative to the theoretical reflection spectrum shown in FIG. 6, presumably due to small calibration errors of the growth per oscillation.

### Example #2

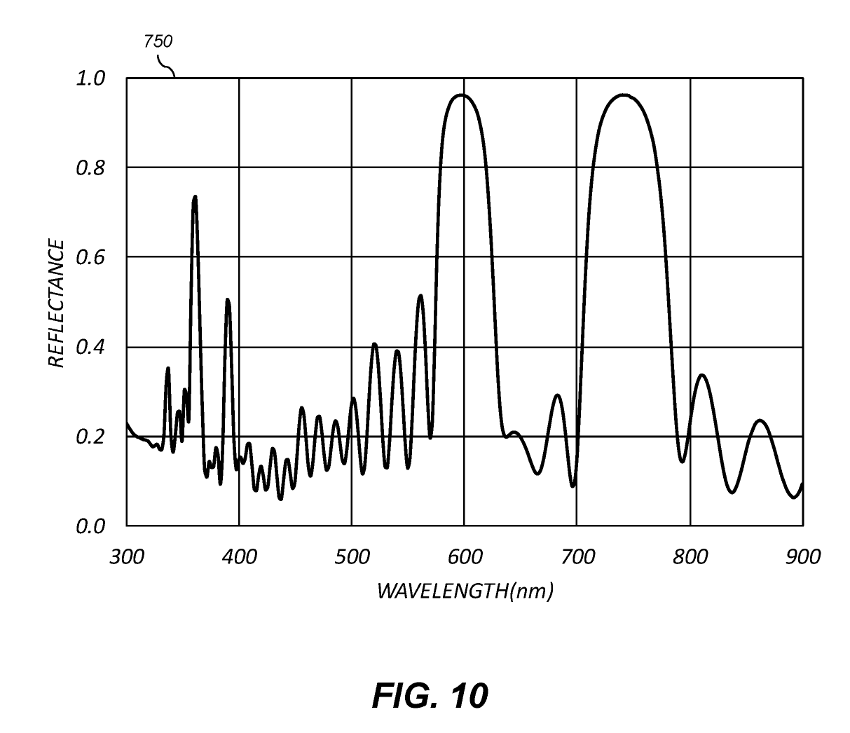

To demonstrate that the reflection bands can easily be shifted, and that errors in the laydown calibrations were likely responsible for the shifts observed in FIG. 9, the x-axis of target refractive index profile in FIG. 5 was stretched by 15% and a new table of gas flows versus oscillation number was determined. The total number of oscillation now became 12,001 and required 149 minutes to complete. The measured reflection spectrum of the resulting thin-film filter is shown in the graph 750 of FIG. 10. It can be observed that the peak wavelengths of the reflection bands have both been shifted in the red direction as expected.

In the exemplary embodiment illustrated in FIG. 4, the first reactive gaseous material is a homogeneous mixture of first and second reactive precursors (i.e., metal precursors M₁ and M₂) and the second reactive gaseous material contains a third reactive precursor (i.e., reactant O). However, it will be obvious to one skilled in the art that this configuration can be generalized so that the first and second reactive gaseous materials can include different numbers of reactive precursors. For example, the first reactive gaseous material can include a mixture of more than two reactive precursors. Similarly, the second reactive gaseous material can include a mixture of a plurality of reactive precursors. The mixing systems 640, 645 will provide a homogeneous mixture of the associated reactive precursors.

It is clear that other refractive index profiles can be obtained by this method in a relatively short period of time compared to conventional ALD and with better layer thickness and composition control than are obtainable using sputtering processes. While the exemplary compositionally-graded thin films described here have related to the formation of compositionally-graded thin film optical interference filters (e.g., rugate filters), it will be obvious to one skilled in the art that the same fabrication processes can be used to form other types of thin-film devices including compositionally-graded thin films. The invention is particularly well-suited to thin-film devices which require depositing layers having different compositions to provide different optical, electrical or mechanical properties.

Other examples of thin-film optical devices that can be fabricated using the process of the present invention would include optical waveguides that are useful for guiding light on the surface of a substrate. Such devices require varying the refractive index as a function of height above the substrate and can be fabricated using the method described earlier.

Encapsulation layers can be formed from compositionally-graded thin-film layers such that the permeability to oxygen and water vapor is improved over single component thin films. In semiconductor devices, compositionally-graded thin films are useful to control the electrical properties at critical interfaces and within the bulk of the material layer. For instance, it can be useful to controlling the band-gap and energy in semiconductor layers. Multiple applications benefit from using compositionally-graded films to tune the mechanical stress and strain properties of thin-film devices. Compositionally-graded thin-films of Al₂O₃ and SiO₂ are useful as encapsulation layers and can be formed using the process of the present invention using TMA and SiCl₃H as M₁ and M₂ in the homogenous gas mixture in first reactive gas.

The invention has been described in detail with particular reference to certain preferred embodiments thereof, but it will be understood that variations and modifications can be effected within the spirit and scope of the invention.

### PARTS LIST

15 external environment
30 deposition head
94 working distance
97 substrate
98 motion arrow
110 gas slot
112 output slot
114 exhaust slot
134 output face
200 SALD system
205 deposition subsystem
210 deposition unit
270 relative motion system
280 substrate positioner module
305 deposition zone
308 inert zone
309 inert zone
313 first reactive gas zone
314 purge zone
315 second reactive gas zone
320 output slot
400 deposition system
410 mass flow controller
415 inert gas conduit
420 inert gas source
424 exhaust conduit
434 gas inlet conduit
436 gas inlet conduit
438 gas inlet conduit
500 first reactive gas species conduit
505 bubbler
510 second reactive gas species conduit
515 bubbler
520 third reactive gas species conduit
525 bubbler
530 inert gas conduit
540 inert gas conduit
600 controller
620 wiring
630 wiring
640 mixing system
645 mixing system
650 stage
660 motor
700 graph
710 graph
720 graph
730 graph
740 graph
750 graph

1. A spatial atomic layer deposition system for fabrication of a compositionally-graded thin film, comprising:
a substrate support mechanism for supporting a substrate, the substrate having a substrate surface;
a deposition unit having a first reactive gas zone and a second reactive gas zone,
a mixing system that provides a first reactive gaseous material including a controllable ratio of a first reactive gaseous species and a second reactive gaseous species;
a gas delivery system for supplying the first reactive gaseous material to the first reactive gas zone and a second reactive gaseous material including a third reactive gaseous species to the second reactive gas zone;
a relative motion system for causing relative motion between the deposition unit and the substrate according to a specified motion profile such that the substrate is sequentially exposed to the first and second reactive gaseous materials in the first and second reactive gas zones, respectively, thereby depositing material on the substrate; and
a controller for controlling the mixing system to vary the ratio of the first and second reactive gaseous materials during the relative motion such that the combination of the controlling the mixing system and the motion profile causes the deposition of a thin film having a variable composition as a function of height above the substrate surface.

2. The spatial atomic layer deposition system of claim 1, wherein controlling the mixing system includes:
receiving a material property profile specifying a desired material property of the deposited material as a function of height above the substrate surface;
receiving a first calibration function relating the desired material property of the deposited material to the ratio of the first and second reactive gaseous species;
receiving a second calibration function relating a growth rate of the deposited material to the ratio of the first and second reactive gaseous species; and
controlling the ratio of the first and second reactive gaseous species as a function of time responsive to the material property profile and the first and second calibration functions.

3. The spatial atomic layer deposition system of claim 1, wherein the deposition unit includes a delivery head having an output face, and wherein a pressure generated by a flow of gaseous material through openings in the output face create a gas fluid bearing that maintains a substantially uniform distance between the output face of the delivery head and the substrate.

4. The spatial atomic layer deposition system of claim 1, wherein the mixing system mixes the first and second reactive gaseous species by merging a gas flow of the first reactive gaseous species in a first conduit and a gas flow of the second reactive gaseous species in a second conduit to form a combined gas flow in a third conduit.

5. The spatial atomic layer deposition system of claim 1, wherein the mixing system also mixes an inert gaseous material together with the first reactive gaseous species and the second reactive gaseous species.

6. The spatial atomic layer deposition system of claim 1, wherein the deposition unit further includes an inert gas zone separating the first reactive gas zone and the second reactive gas zone, and wherein the gas delivery system supplies an inert gaseous material to the inert gas zone.

7. The spatial atomic layer deposition system of claim 1, wherein the first and second reactive gas zones are smaller than the substrate, and wherein the substrate is moved through the first and second reactive gas zones to expose the substrate to the first and second reactive gaseous materials.

8. The spatial atomic layer deposition system of claim 1, wherein the substrate is larger than the deposition head, and wherein a first portion of the substrate is in the first reactive gas zone at the same time that a second portion of the substrate is in the second reactive gas zone.

9. The spatial atomic layer deposition system of claim 1, wherein the entire substrate fits within the first reactive gas zone and within the second reactive gas zone.

10. The spatial atomic layer deposition system of claim 9, further including an inert gas zone separating the first reactive gas zone and the second reactive gas zone, and wherein the inert gas zone is smaller than the substrate such that a first portion of the substrate is in the first reactive gas zone at the same time that a second portion of the substrate is in the second reactive gas zone.

11. The spatial atomic layer deposition system of claim 9, further including an inert gas zone separating the first reactive gas zone and the second reactive gas zone, and wherein the inert gas zone is larger than the substrate such that the entire substrate is exposed to the first reactive gas in the first reactive gas zone prior to being exposed to the second reactive gas in the second reactive gas zone.

12. The spatial atomic layer deposition system of claim 1, wherein the first reactive gas zone and the second reactive gas zone are arranged in a linear pattern in the deposition unit, and wherein the relative motion system causes relative motion between the deposition unit and the substrate according to a linear motion profile.

13. The spatial atomic layer deposition system of claim 1, wherein the first reactive gas zone and the second reactive gas zone are arranged in a radial pattern in the deposition unit, and wherein the relative motion system causes relative motion between the deposition unit and the substrate according to a circular motion profile.
